(19) United States
(12) Patent Application Publication
(10) Pub. No.: US 2008/0254605 A1
(43) Pub. Date: Oct. 16, 2008

(54) METHOD OF REDUCING THE INTERFACIAL OXIDE THICKNESS

(75) Inventors: David Brunco, Tervuren (BE); Lars-Ake Ragnarsson, Leuven (BE); Stefan De Gendt, Wijnegem (BE); Zsolt Tokei, Heverlee (BE)

Correspondence Address: KNOBBE MARTENS OLSON & BEAR LLP, 2040 MAIN STREET, FOURTEENTH FLOOR, IRVINE, CA, 92614, US

(73) Assignees: Interuniversitair Microelektronica Centrum (IMEC), Leuven (BE); Intel Corporation, Santa Clara, CA (US)

(21) Appl. No.: 11/735,926

(22) Filed: Apr. 16, 2007

(51) Int. Cl. H01L 21/3205

(52) U.S. Cl. 438/585; 257/E21.294

(57) ABSTRACT

One inventive aspect is related to a method of minimizing the final thickness of an interfacial oxide layer between a semiconductor material and a high dielectric constant material. The method comprises depositing a covering layer on the high dielectric constant material. The method further comprises removing adsorbed/absorbed water from the high dielectric constant material prior to depositing the covering layer. The removal of adsorbed/absorbed water is preferably done by a degas treatment. The covering layer may be a gate electrode or a spacer dielectric.

### BACKGROUND OF THE INVENTION

1. Field of the Invention

The invention is related to methods of manufacturing metal-oxide-semiconductor (MOS) structures. Particularly, the invention is related to MOS-structures having a gate stack comprising a material with high dielectric constant.

2. Description of the Related Technology

It is known that the performance of metal-oxide-semiconductor structures may be increased for a given power consumption when the equivalent oxide thickness (EOT) is scaled to lower values while maintaining adequately low gate leakage currents. The scaling of the EOT requires the integration of gate dielectric materials with dielectric constants κ higher than the about 3.9 value of SiO₂. Those dielectric materials are referred to as high-κ materials—i.e. having a high dielectric constant. Examples of such materials are Al₂O₃, HfO₂, Hf-silicate and ZrO₂.

The gate stack of such a MOS structure then generally comprises a semiconductor layer (e.g. Si), optionally an interfacial layer which typically comprises an oxide of the semiconductor (e.g. SiO₂), a layer of a high-κ dielectric material and a gate electrode layer (e.g. a gate metal such as TaN, TaCN, TaC, or TiN). For high performance transistors utilizing high-κ dielectrics an EOT reduction to values of about 1.2 nm and below is desired. This requires a thin interfacial layer.

While EOTs below about 1.2 nm are readily achievable in as-deposited gate stacks, the application of thermal budgets typically result in a growth of the interfacial layer dielectric and hence an undesired increase in the EOT.

It is known that the incorporation of nitrogen at the interface between Si and interfacial SiO₂ suppresses oxidation and limits EOT growth. However, this is typically accompanied by an undesired decrease in carrier mobility. The deposition of metallic getter layers, e.g., Ti and Hf are also known to soak up excess oxygen, thus limiting EOT growth. However, poor electrical performance typically results.

### SUMMARY OF CERTAIN INVENTIVE ASPECTS

Certain inventive aspects aim to minimize the final thickness of the interfacial layer dielectric in a semiconductor structure without incurring the drawbacks of the prior art, and to provide a method of reducing the re-growth of the interfacial layer dielectric in a semiconductor structure which does not adversely affect the performance of the structure.

It is a further object of certain inventive aspects to provide a method of manufacturing a transistor gate stack which overcomes the drawbacks of prior art methods, and to provide transistor gates with improved performance compared to prior art gate stacks.

The objects are achieved by providing a method, as set out in the appended claims, in which after depositing a high-κ dielectric layer and before depositing a covering layer (for capping or sealing, e.g. gate electrode, spacer dielectric, etc.) on or against the high-κ layer, a degas treatment is performed in order to remove water (and/or other volatile species) which have adsorbed to the high-κ layer and/or were absorbed by the high-κ layer. Hence the method according to one aspect prevents that adsorbed and/or absorbed water from diffusing through the high-κ layer to an interface of the semiconductor material. The diffused water would oxidize the semiconductor material when thermal budgets are applied, leading to the formation and/or growth of an oxide of the semiconductor which increases the EOT. As high-κ dielectrics are strong adsorbers/absorbers of water, the environment following degas and prior to deposition of the covering layer should preferably be controlled to minimize water exposure. By this method, water “captured” between the dielectric and the covering layer is minimized.

According to a first aspect of the invention, there is thus provided a method of providing a gate stack on a semiconductor structure comprising the steps of: providing a semiconductor structure comprising a semiconductor material and optionally comprising an interfacial oxide layer, depositing on the semiconductor structure a high-κ layer comprising a material with a dielectric constant κ higher than the dielectric constant of SiO₂ and depositing a gate electrode on the high-κ layer. In between the step of depositing a high-κ layer and the step of depositing a gate electrode, the method comprises the step of removing adsorbed and/or absorbed water from the high-κ layer.

Preferably, the step of removing adsorbed and/or absorbed water comprises applying a degas treatment. More preferably, the degas treatment comprises keeping the semiconductor structure in an ambient at a temperature in the range between approximately 300° C. and 700° C. during a length of time in the range approximately between 30 s and 300 s. Even more preferably, the temperature lies in the range approximately between 350° C. and 600° C. and/or the length of time is in the range approximately between 90 sand 180 s.

Preferably, the step of removing adsorbed and/or absorbed water comprises keeping the semiconductor structure in an ambient at a pressure less than or equal to about 10 Torr. More preferably, the pressure lies in the range approximately between 0.5 mTorr and 10 mTorr when a carrier gas (e.g., Ar, N₂) is used and less than about 1 mTorr when no carrier gas is used.

Preferably, in between the step of removing adsorbed and/or absorbed water and the step of depositing a gate electrode, the ambient pressure is maintained at a partial vacuum, preferably less than or equal to about 10 Torr.

Preferably, the step of removing adsorbed and/or absorbed water comprises keeping the semiconductor structure in an ambient with a water vapor partial pressure less than or equal to about 10⁻⁴ Torr, preferably less than or equal to about 10⁻⁵ Torr.

Preferably, the step of removing adsorbed and/or absorbed water and the step of depositing a gate electrode are performed in separate process chambers. More preferably, the method according to the first aspect of the invention comprises the step of transferring the semiconductor structure between the separate process chambers under ambient conditions having a water vapor partial pressure less than or equal to 10⁻³ Torr. The step of transferring the semiconductor structure is preferably performed promptly, more preferably in less than 5 minutes.

Preferably, the steps of removing adsorbed and/or absorbed water and of depositing a gate electrode are performed in the same process chamber.

Preferably, the degas treatment is carried out in an ambient comprising a carrier gas chosen from the group comprising: Ar and N₂. The flow of this carrier gas helps to flush out the degassed species from the process vessel (e.g. chamber).

Preferably, the method according to the first aspect of the invention further comprises, after the step of depositing a gate electrode, the step of applying a thermal budget.

Preferably, the material with a dielectric constant higher than the dielectric constant of SiO₂ is chosen from the group comprising: Al₂O₃, HfO₂, Hf-silicate, Hf-aluminate, ZrO₂, Zr-silicate, Zr-aluminate, La-aluminate, Hf-lanthanate, Zr-lanthanates, and Hf-zirconates. Preferably, the gate electrode comprises a metal or the gate electrode is poly Si or fully silicided poly Si (FUSI).

Preferably, the semiconductor structure comprises the interfacial oxide layer, wherein the interfacial oxide layer is provided on the semiconductor material, and wherein the interfacial oxide layer essentially comprises an oxide of the semiconductor material.

According to a second aspect of the invention, there is provided a method of providing a spacer dielectric against a gate stack, the method comprising the steps of: providing a gate stack comprising a high-κ layer comprising a material with a dielectric constant κ higher than the dielectric constant of SiO₂, patterning the gate stack to obtain a patterned gate stack, thereby exposing the high-κ layer and depositing a spacer dielectric, thereby covering (capping or sealing) the high-κ layer at least at one side. In between the step of patterning the gate stack and the step of depositing a spacer dielectric, the method comprises the step of removing adsorbed and/or absorbed water from the high-κ layer.

Preferably, the step of removing adsorbed and/or absorbed water comprises applying a degas treatment. More preferably, the degas treatment comprises keeping the patterned gate stack in an ambient at a temperature in the range approximately between 300° C. and 700° C. and preferably in the range approximately between 350° C. and 600° C., during a length of time in the range approximately between 30 s and 300 s and preferably in the range approximately between 90 s and 180 s.

Preferably, the step of removing adsorbed and/or absorbed water comprises keeping the patterned gate stack in an ambient at a pressure less than or equal to about 10 Torr and preferably in the range approximately between 0.5 mTorr and 10 mTorr when a carrier gas is used and less than about 1 mTorr when no carrier gas is used.

Preferably, the step of removing adsorbed and/or absorbed water comprises keeping the patterned gate stack in an ambient with a water vapor partial pressure less than or equal to about 10⁻⁴ Torr, preferably less than or equal to about 10⁻⁵ Torr.

Preferably, in between the step of removing adsorbed and/or absorbed water and the step of depositing a spacer dielectric, the ambient pressure is maintained at a partial vacuum, preferably less than or equal to about 10 Torr.

Preferably, the step of removing adsorbed and/or absorbed water and the step of depositing a spacer dielectric are performed in separate process chambers. More preferably, the method according to the second aspect of the invention comprises the step of transferring the patterned gate stack between the separate process chambers under ambient conditions having a water vapor partial pressure less than or equal to about 10⁻³ Torr. The step of transferring the patterned gate stack is preferably performed promptly, more preferably in less than about 5 minutes.

Preferably, the steps of removing adsorbed and/or absorbed water and of depositing a spacer dielectric are performed in the same process chamber.

Preferably, the spacer dielectric is the first of multiple spacer dielectrics deposited.

Preferably, the method according to the second aspect of the invention further comprises, after the step of depositing a spacer dielectric, the step of patterning the spacer dielectric.

Preferably, the method according to the second aspect of the invention further comprises, after the step of depositing a spacer dielectric, the step of applying a thermal budget.

According to one inventive aspect, there is provided a method of minimizing the final thickness of an interfacial oxide layer between a semiconductor material and a high-κ layer. The high-κ layer comprises a material with a dielectric constant κ higher than the dielectric constant of SiO₂. The method according to the third aspect of the invention comprises the steps of depositing a covering layer on the high-κ layer and of removing adsorbed and/or absorbed water from the high-κ layer prior to the step of depositing the covering layer. The covering layer is a layer that covers at least partially the high-κ layer. The covering layer may be a capping or sealing layer.

Preferably, the step of removing adsorbed and/or absorbed water comprises applying a degas treatment.

Preferably, after the step of depositing a covering layer, a step of applying a thermal budget is carried out.

Preferably, the covering layer comprises a gate electrode layer and/or a spacer dielectric.

### BRIEF DESCRIPTION OF THE DRAWINGS

All drawings are intended to illustrate some aspects and embodiments of the invention. The drawings described are schematic and are non-limiting.

FIG. 1 represents an as-deposited gate stack (1) of a semiconductor device comprising a semiconductor layer (10), an interfacial layer (11) of an oxide of the semiconductor, a layer (12) of a material with high dielectric constant to which water is adsorbed at a surface layer (13) and a gate electrode layer (14). There may also be some degree of water absorbed into the high-κ layer (12).

FIG. 2 presents the measured equivalent oxide thickness for a number of experiments in which the wafers received a degas treatment to remove adsorbed/absorbed water prior to gate electrode deposition (except for E1) and a spike anneal at 1030° C. (100° C./s ramp up, about 0.3 s at 1030° C., 65° C./s ramp down) performed subsequent to the deposition of the gate electrode (except for E6 and E7). The degas temperatures and times were as follows: E1 no degas; E2 degas at 330° C. for 40 s; E3 degas at 350° C. for 180 s; E4 degas at 450° C. for 180 s; E5 degas at 550° C. for 180 s; E6 degas at 330° C. for 40 s but with the anneal at 650° C. for 1 min; E7 degas at 330° C. for 40 s but with thermal treatments limited to a maximum of 520° C. The degas for E2, E6 and E7 was performed under vacuum with a base pressure of about 10⁻⁷ Torr while the degas for E3-E5 was performed at a pressure of 2 mTorr in an ambient of Ar flowing at 28 standard cubic centimeters per minute (sccm).

FIG. 3 presents the normalized volume of degassed water from a single silicon wafer with 4 nm of HfO₂ under different situations: (31): first degas treatment to remove the adsorbed water (reference value of 100%); (32): a second degas performed following subjecting the wafer (31) to 25 minutes in a cryo-pumped load lock; (33): a third degas performed following exposure of wafer (32) in air for 5 minutes; (34): a fourth degas, following 1 week air exposure for wafer (33). All degas volumes in this figure are normalized to the first degas such that (31) is 100% by definition.

FIG. 4 plots the EOT versus the peak carrier mobility for wafers having received degas treatments to remove adsorbed/absorbed water prior to gate electrode deposition: (42): degas treatment at 330° C. for 40 s; (41): all other degas treatments for 180 s.

FIG. 5 represents a flow chart of the method of manufacturing a gate stack with a degas prior to gate electrode deposition according to one embodiment.

FIG. 6 represents a flow chart of the method of manufacturing a gate stack with a degas prior to a spacer dielectric deposition according to one embodiment.

FIG. 7 represents a gate stack (7) with patterned spacers (72) of a semiconductor device comprising a semiconductor layer (10), an interfacial layer (11) of an oxide of the semiconductor, a layer (12) of a material with high dielectric constant to which water is adsorbed at surfaces (71) exposed prior to spacer deposition, and a gate electrode layer (14). There may also be some degree of water absorbed into the high-κ layer (12). Elements 10, 11, 12, and 14 are the same as in FIG. 1. Element 71 is analogous to 13, but for exposure prior to spacer deposition instead of prior to gate electrode deposition.

FIG. 8 presents X-ray Photoelectron Spectroscopy (XPS) results for the increase in interfacial SiO₂ thickness for anneals of an initial stack of Si substrate/6 Å SiO₂/20 Å HfO₂ with and without a 350° C. 3 min degas. As a note, this study was performed on test wafers with blanket (unpatterned) stacks, not on actual device structures.

### DETAILED DESCRIPTION OF CERTAIN INVENTIVE EMBODIMENTS

Embodiments of the present invention will now be described in detail with reference to the attached figures, the invention is not limited thereto but is limited by the claims. The drawings described are schematic and are non-limiting. In the drawings, the size of some of the elements may be exaggerated and not drawn on scale for illustrative purposes. The dimensions and the relative dimensions do not necessarily correspond to actual reductions to practice of the invention. Those skilled in the art can recognize numerous variations and modifications of this invention that are encompassed by its scope. Accordingly, the description of preferred embodiments should not be deemed to limit the scope of the present invention.

Furthermore, the terms first, second and the like in the description and in the claims are used for distinguishing between similar elements and not necessarily for describing a sequential or chronological order. It is to be understood that the terms so used are interchangeable under appropriate circumstances and that the embodiments of the invention described herein are capable of operation in other sequences than described or illustrated herein.

Moreover, the terms top, bottom, left, right, over, under and the like in the description and the claims are used for descriptive purposes and not necessarily for describing relative positions. The terms so used are interchangeable under appropriate circumstances and the embodiments of the invention described herein can operate in other orientations than described or illustrated herein. For example “left” and “right” from an element indicates being located at opposite sides of this element.

It is to be noticed that the term “comprising”, used in the claims, should not be interpreted as being restricted to the means listed thereafter; it does not exclude other elements or steps. Thus, the scope of the expression “a device comprising means A and B” should not be limited to devices consisting only of components A and B. It means that with respect to the present invention, A and B are relevant components of the device.

A first embodiment relates to a method of manufacturing a transistor gate stack on a semiconductor structure, wherein on an interfacial oxide layer of the semiconductor structure a high-κ dielectric layer is deposited. A gate electrode is provided afterwards on the high-κ dielectric layer. The high-κ dielectric layer and the gate electrode are generally provided (deposited) in separate semiconductor manufacturing equipment (tools) or in separate chambers of the same cluster tool. During transport from one manufacturing tool/chamber to another and during handling, the structures may be subjected to atmospheric conditions with varying moisture levels (humidity). High-κ dielectric materials used for microelectronics are typically strong adsorbers of water. The water adsorbs primarily at the surface layer of the high-κ dielectric. Hence, during transport and handling, water has sufficient time to adsorb to (a surface layer of) the high-κ dielectric material. The adsorbed water may be in the form of chemisorbed H₂O and hydroxyl (OH) groups bonded directly to the high-κ dielectric, or physisorbed H₂O that is not directly bonded to the high-κ dielectric but rather to chemisorbed H₂O, OH, and/or other physisorbed H₂O molecules. In practice, there may also be some water and hydroxyls absorbed into the “bulk” of the high-κ dielectric material.

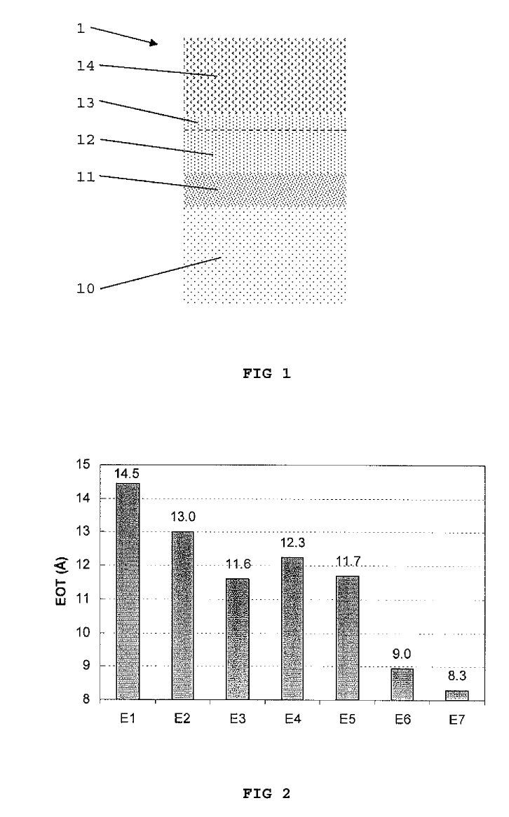

When thereafter a gate electrode is provided on top of the high-κ dielectric, the situation is obtained as depicted in FIG. 1. An as-deposited gate stack 1 is obtained in which water has adsorbed to a surface layer 13 of the high-κ dielectric layer 12. Layer 10 is a semiconductor layer (e.g. Si or Ge), layer 11 represents the interfacial layer (e.g. comprising an oxide of the semiconductor, such as SiO₂ or GeOₓ) and layer 14 is the gate electrode (e.g. a gate metal).

In order to obtain a gate stack with targeted properties, one or more thermal budgets are applied. The hottest of these thermal budgets is typically an activation anneal to activate dopants and to anneal out ion implantation related damage. This activation anneal is typically carried out for silicon-based technologies at temperatures in excess of about 900° C. and often in excess of about 1000° C.

However, the term “thermal budget” in this patent is not restricted to only activation anneal steps at such high (>900° C.) temperatures. In fact, there exist a number of alternative technologies that do not subject the gate stack to such high temperatures. “Replacement gate” is one such technology, for which a dummy gate stack is used through the activation anneal and possibly additional steps, followed by removal of this dummy gate stack and fabrication of the final gate stack. Another example is the Solid Phase Epitaxial Regrowth (SPER) flow, in which the doped semiconductor regions are amorphized prior to a low temperature (about 600° C.) SPER anneal which serves to get a high fraction of electrically activated dopant atoms at a low activation temperature. Ge-based devices is yet another example, for which anneals with peak temperatures ranging approximately between 400 and 600° C. typically achieve sufficient dopant activation. Finally, in addition to dopant activation, semiconductor devices may be subjected to thermal budgets from various deposition and anneal steps done as a part of post gate stack processing.

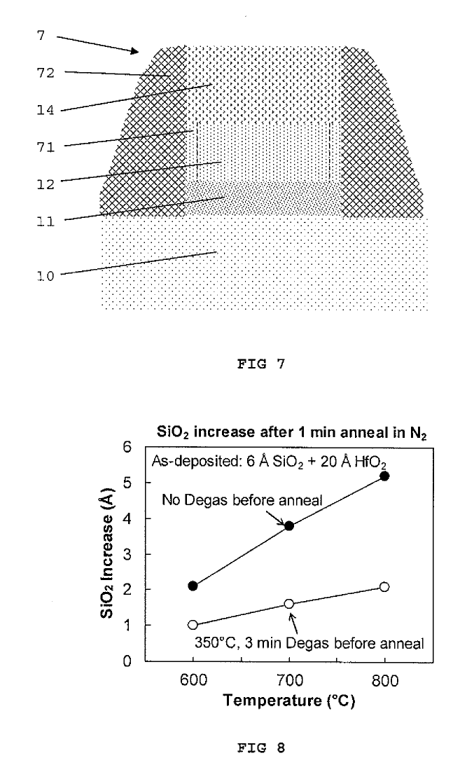

The inventors believe that the high temperatures to which the gate stack 1 is subjected during a thermal budget cause some of the adsorbed and absorbed water to diffuse to the interface between the semiconductor 10 and its oxide 11 where it oxidizes the semiconductor. Hence, the application of thermal budgets leads to a growth of the interfacial oxide layer 11, which deteriorates gate performance. The diffusivity of oxidants (e.g. water) and oxidation of the semiconductor surface are strongly temperature dependent. A higher thermal budget (higher temperature) will enhance the growth of the interfacial oxide layer more than a low thermal budget (e.g. at about 600° C.) for a given gate stack; however, even lower thermal budgets give EOT growth. The data of FIG. 2 provide an example: E6 has an EOT 0.7 Å larger than that of E7 despite only the addition of a 650° C. thermal budget. FIG. 8 shows that the benefit of the degas increases with temperature, but still exists even down to the lowest measured anneal temperature of 600° C.

The inventors have observed that when the adsorbed/absorbed water is totally or largely removed before depositing the gate electrode, the growth of the interfacial oxide layer 11 during application of a thermal budget (e.g. a thermal anneal to activate implanted dopants) becomes less pronounced. The removal of adsorbed and/or absorbed water from a sample by a thermal treatment, whereby the adsorbed/absorbed water leaves the sample in gaseous phase and is evacuated from the treatment chamber is generally known as degas. A degas treatment is preferably performed under reduced pressure conditions and in a water-free ambient. For the purposes of the present description, by reduced pressure conditions are understood pressures lower than about 10 Torr and preferably lower than about 10 mTorr. By water free ambient are understood a water vapor partial pressure lower than about 10⁻⁴. Torr and preferably lower than about 10⁻⁵ Torr.

The removal of the adsorbed/absorbed water by degassing should preferably be performed immediately prior to the gate electrode deposition (deposition of layer 14), in order to prevent water re-adsorption (caused by e.g. humidity in the ambient surrounding the wafer) when e.g. transferring the wafer from the degas chamber to the chamber for gate electrode deposition. Preferably, the removal of adsorbed water is carried out in-situ, namely in the chamber that provides for deposition of the gate electrode. If the degas treatment is not performed in-situ in the gate electrode deposition chamber, then it should advantageously be performed in a clustered tool in which the wafer is exposed to a controlled atmosphere during the transfer from the degas chamber to the gate electrode deposition chamber.

The degas treatments are performed in front-end-of-line (FEOL) process technology, more specific at the gate stack deposition level. The degas treatment should substantially completely remove the adsorbed/absorbed water from the gate dielectric in order to reduce the interfacial oxide layer re-growth.

The removal of adsorbed/absorbed water is preferably performed by a degas treatment of the semiconductor structure—prior to gate electrode deposition—at temperatures approximately between 300° C. and 700° C., preferably between approximately 350° C. and 600° C. A minimal duration of the degas treatment is needed to remove most of the water and/or moisture. Once this portion of time has elapsed, the exact duration of the degas treatment is not critical anymore. Preferred duration for the degas treatment lies approximately between 30 s and 300 s, more preferably between approximately 90 s and 180 s. The duration may be chosen as a function of temperature. Generally, the higher the degas temperature, the shorter the required duration. For throughput concerns, the length of time for the removal of adsorbed water should preferably be limited to a maximum of about 3 minutes. Appropriate degas conditions will serve to remove essentially all the physisorbed H₂O and much of the chemisorbed H₂O and OH. Hydroxyl (OH) removal will typically arise from a “condensation reaction” in which neighboring OH groups react to form an H₂O molecule which is degassed and leaving behind a bridging oxygen bonded to 2 cations in the high-κ dielectric.

It is preferable to remove the adsorbed/absorbed water in a reduced pressure ambient, preferably with a very low water vapor content. Preferably, reduced pressures less than or equal to about 10 Torr are used. More preferably between about 0.5 mTorr and 10 mTorr when a carrier gas is used and less than about 1 mTorr when no carrier gas is used. The water vapor content (water vapor partial pressure) is preferably lower than about 10⁻⁵ Torr. A carrier gas, such as Ar or N₂ may in addition be beneficial. The application of a reduced pressure ambient as part of the degas treatment can provide for a more effective removal of water from the wafer (high-κ layer). During the degas treatment, the water extracted from the wafer is preferably evacuated from the chamber.

FIG. 2 gives experimental EOT results for different degas conditions prior to gate electrode deposition on 200 mm device wafers. The wafers used for the experiments reported in FIG. 2 all received a spike anneal at 1030° C., except for experiment E6, which received a 650° C., 1 minute anneal and experiment E7, which received no high temperature anneal. Experiment E1 was performed without any degas treatment and gives the highest EOT. The degas treatment of E2 (330° C. for 40 s under vacuum with a base pressure of about 10-7 Torr) prior to gate electrode deposition results in an EOT reduction of about 1.5 Å. Degas treatments E3-E5, respectively at 350° C., 450° C. and 550° C., all for 180 s, all significantly reduced the EOT compared to E1, with a maximal reduction of 2.9 Å for E3. Degas treatments E3-E5 were performed at a pressure of 2 mTorr in an ambient of Ar flowing at 28 standard cubic centimeters per minute (sccm). A lower thermal budget E6 results in significantly lower EOT as a result of the strong temperature dependency of the interfacial layer growth as described previously. With a degas treatment (330° C. for 40 s) prior to gate electrode deposition the EOT of E6 (650° C. thermal budget) is 0.7 Å thicker than with a lower thermal budget E7. With better degas treatments as in E3-E5, the EOT with low thermal budget is expected to be further reduced. The advantage of the embodiment is thus still significant even at low thermal budgets.

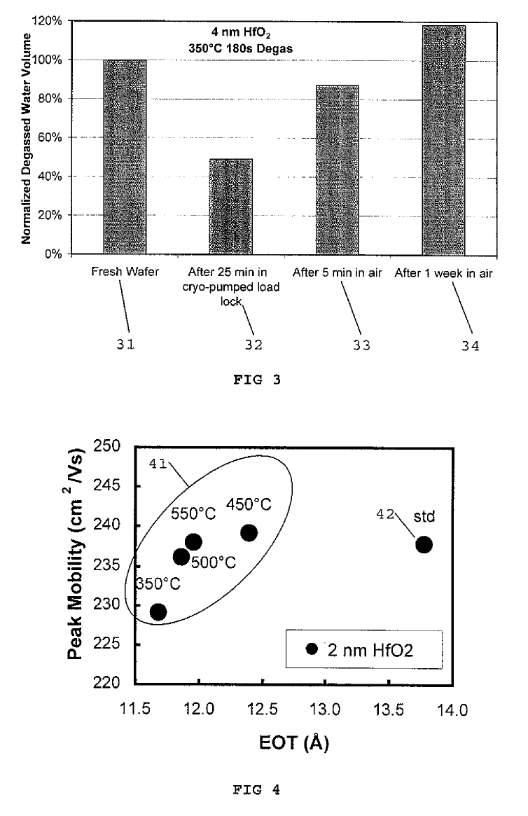

It is important for the embodiment to be effective that water re-adsorption back onto the high-κ dielectric layer is minimized between the removal of adsorbed water (degas treatment) and the deposition of the covering layer (e.g. gate electrode, spacer dielectric, etc.). This is shown in the experiment of FIG. 3. On a wafer with high-κ dielectric layer, an amount of water was desorbed by degas treatment 31. Thereafter, the wafer was kept in a load lock under a(n imperfect) vacuum for 25 minutes, which resulted in half that amount of water being re-adsorbed to the surface of the high-κ dielectric layer. This is evident from the degassed water volume of degas 32. Subsequently, the wafer having undergone degas 32 was kept in air for 5 minutes and degassed again, resulting in the degassed water volumes of degas treatment 33, which show that more than 80% of the original amount of water (of degas 31) already had re-adsorbed. Degas 34 was performed after keeping the wafer in air for one week. An amount of water resulted to have adsorbed exceeding the original amount degassed from the fresh wafer. These experiments show how readily water is adsorbed by the dielectric and the importance of a close coupling between the degas and the covering layer deposition. On the other hand, in an experiment wherein a degassed wafer was transferred to a buffer chamber (3×10⁻⁷ Torr) for 1 minute and then returned for a 2^{nd} degas, no degassed water was detected (not shown in the figure). This shows that with appropriate care (short times and sufficiently low water vapor partial pressures), the degassed surface can be preserved during wafer transfer to the metal gate deposition chamber.

The method of one embodiment allows to reduce interfacial layer re-growth without degrading carrier mobility. Typically, process changes that reduce interfacial layer re-growth result in a significant degradation in carrier mobility. This is the case, for example, for a NH₃ anneal. The data in FIG. 4 show that the degas treatments 41 at 350° C.-550° C. for 180 s result in a significant reduction in equivalent oxide thickness compared to the minor degas treatment 42 at 330° C. for 40 s. The reduction in EOT is accompanied by little or no degradation in peak mobility. As transistor drive current is roughly proportional to the ratio of carrier mobility to EOT, the degas treatments 41 provide an improved device performance.

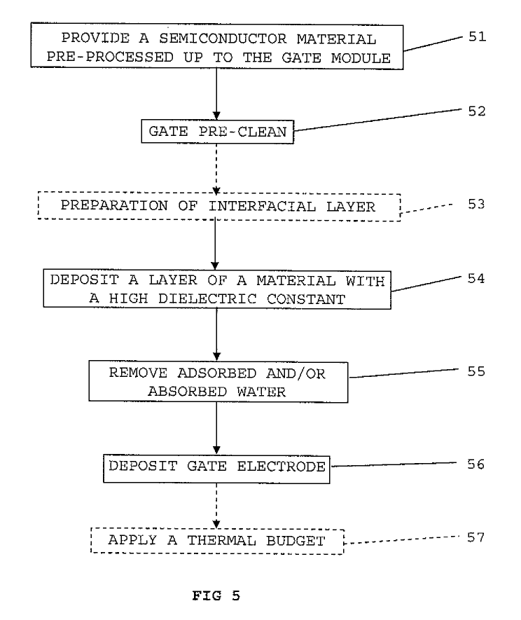

Hence, in a first embodiment, the method for manufacturing a gate stack comprises the steps represented in FIG. 5. In a first step 51 a semiconductor structure is provided, pre-processed up to deposition of the gate module. The semiconductor structure comprises a semiconductor layer 10 and an interfacial oxide layer 11 on top. The interfacial oxide layer will form an interfacial layer between the semiconductor substrate material and the gate stack. Next, in step 52, the areas onto which a gate will be provided are cleaned. In step 53, the interfacial oxide layer is prepared for deposition of a high-κ layer. In the following step 54, a layer of a material having a high dielectric constant (higher than the one of SiO₂) is deposited on the interfacial oxide layer. Following step 54 and prior to step 56, the method provides for the removal of adsorbed/absorbed water or moisture in step 55. The removal is advantageously carried out by a degas treatment at high temperature and optionally at a reduced pressure. Subsequently, in step 56 a gate electrode layer is deposited on the layer of high dielectric constant (high-κ) material. In an optional step 57 following step 56 (a number of intervening process steps not shown in FIG. 5 may be applied in between), a thermal budget may be applied to the manufactured gate stack.

As stated earlier, it is advantageous to the method of one embodiment that steps 55 and 56 are carried out a very short time one after the other. This minimizes water re-adsorption onto the high-κ dielectric layer after the degas treatment. Steps 55 and 56 may be carried out ex-situ (i.e. in different process chambers) or in-situ (in the same process chamber), depending on which technology is used to carry out step 56. In step 56, the deposition of a gate electrode material on a high-κ dielectric layer may be performed according to a number of processes, among others physical vapor deposition (PVD), atomic layer deposition (ALD) and chemical vapor deposition (CVD). If these processes are carried out at comparatively low temperatures (below about 350° C.), process steps 55 and 56 would need separate process chambers. In this latter case, the transfer of the wafer from the degas chamber to the gate electrode deposition chamber should preferably be performed in a minimal time span (less than about 5 minutes) and with a minimal water vapor exposure of the wafer. In practice, this would typically require a cluster tool with transfer chambers under reduced pressure or vacuum and preferably under a reduced water vapor partial pressure ambient. As the wafer does not instantaneously cool to room temperature upon removal from the degas chamber, a short time span for wafer transfer to the gate electrode deposition chamber allows to keep the wafer at an elevated temperature (the wafer remains warm), which minimizes water re-adsorption onto the high-κ layer. In a preferred embodiment, the wafer during transfer remains at a temperature equal to or above about 100° C.

In the case of higher gate electrode deposition temperatures, steps 55 and 56 may be carried out either in separate process chambers as for low temperature gate electrode depositions, or in the same process chamber. In practice, PVD metal gates are typically deposited below 350° C. and may thus require separate chambers on a cluster tool. For the case of ALD processes, which are typically performed between about 350° C. and 450° C., and CVD processes, which are typically between about 600° C. and 700° C., the degas treatment could be done either in a dedicated (clustered) degas chamber or in the deposition chamber. If the degas is to be performed in the deposition chamber, the degas treatment should be carried out for a sufficient length of time in order to remove sufficient water prior to deposition of the gate electrode.

In a second embodiment, the method of the first embodiment is applied to the case in which a high-κ dielectric layer is applied directly onto a semiconductor material (e.g. Si). In this case, the interfacial oxide layer 11 of FIG. 1 is initially absent. Without a treatment to remove adsorbed/absorbed water according to one embodiment, absorbed and/or adsorbed water may diffuse through the high-κ dielectric layer to the interface with the semiconductor material and oxidize the semiconductor material during application of a thermal budget. Hence, in the present embodiment a degas treatment prior to gate electrode deposition would prevent, or at least minimize the formation of an interfacial layer of an oxide of the semiconductor. In the present embodiment, all method steps of FIG. 5 apply, except for step 53, as an initial interfacial oxide layer is absent. Hence, for the second embodiment, step 53 is optional.

According to a third embodiment of the invention, adsorbed/absorbed water is removed after patterning (etching) the gate stack and prior to spacer deposition. This is illustrated in FIG. 7. When a gate stack such as the one depicted in FIG. 1 is patterned, the sidewalls 71 of the patterned gate stack and hence also of the high-κ dielectric layer 12 are exposed. Water (e.g. water vapor present in the surrounding environment) may adsorb onto the exposed surfaces of the high-κ dielectric layer and potentially diffuse into this layer. A degas treatment prior to deposition of spacer 72 will remove adsorbed/absorbed water from the sides of the patterned high-κ dielectric layer, reducing further the interfacial oxide layer re-growth during spacer deposition and subsequent high temperature anneals, thus minimizing the final EOT.

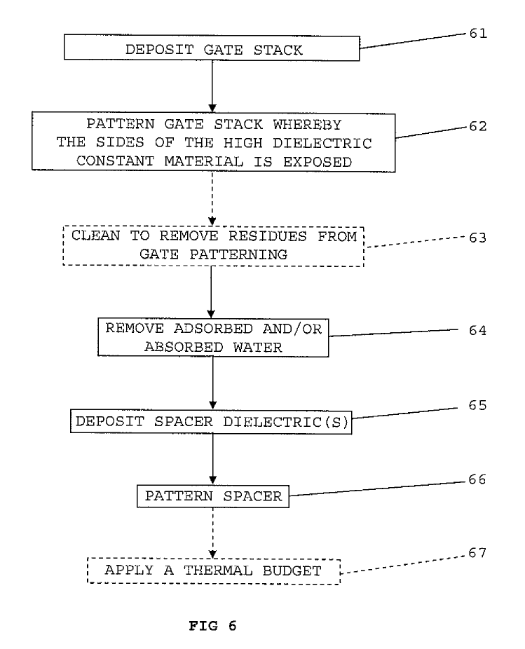

FIG. 6 shows the different method steps for carrying out the third embodiment of the invention. In step 61, a gate stack is deposited. Step 61 may comprise one or more of steps 51 to 56 of FIG. 5. Next, in step 62, the gate stack is patterned. Such patterning may comprise a photolithography and a (typically dry) etch. The patterning results in the sides of the gate stack, and hence also the sides of the high-κ dielectric to be exposed. The ambient to which the sides are exposed may contain water (water vapor), which may adsorb to and/or be absorbed by the high-κ dielectric layer. The exposure may thus be a source of water adsorption/absorption (in)to the sides of the high-κ dielectric layer.

Subsequently, an optional cleaning step 63 to remove residues from the gate electrode patterning may be carried out. This step typically comprises a wet clean, and hence may also be a source of water adsorption/absorption (in)to the high-κ dielectric layer from the exposed sides.

According to the third embodiment of the present invention, after step 63 (or step 62 if step 63 is not carried out) and prior to step 65, step 64 is performed, in which water which has adsorbed to the sides of the high-κ dielectric layer and/or has absorbed into that layer is removed. The removal of adsorbed/absorbed water may be performed by a degas treatment, for which the same conditions as for the degas treatment prior to gate electrode deposition (see step 55 of FIG. 5) may be advantageous.

Next, in step 65 one or more spacer dielectrics are deposited, which cap or seal the sides of the high-κ dielectric layer. Spacers 72 can consist of a single deposited layer e.g. SiO₂ or Si₃N₄ or 2 or more layers e.g. SiO₂/Si₃N₄ and SiO₂/Si₃N₄/SiO₂. A key element is that step 64 needs to be done either in situ in the chamber for the deposition of the first layer of the spacer, or with a controlled environment during transfer between the chamber in which step 64 is performed (e.g. a degas chamber) and the chamber for the deposition of the first spacer layer.

After the step 65 of spacer deposition, the method proceeds to step 66 of spacer patterning. Spacers are typically patterned by self aligned dry etch with optional wet etch. Following step 66 (a number of intervening process steps not shown in FIG. 6 may be applied in between), a step 67 may be carried out, in which one or more thermal budgets are applied to the semiconductor structure. These thermal budgets may be the ones of step 57 (i.e. steps 61-66 may be performed prior to step 57, but after step 56).

An additional advantage of the method is that all the method steps can typically be performed with existing manufacturing facilities. Most cluster facilities for semiconductor processing already comprise one or more chambers for heating the semiconductor structures and for applying partial vacuum (reduced pressure) atmospheres. Hence, the degas treatments with which adsorbed water can be removed may be implemented into the semiconductor manufacturing process, often without requiring additional apparatuses.

The methods generally cover any use of a degas coupled with a controlled environment prior to deposition of a capping or sealing layer over or against a high-κ gate dielectric. It will be apparent to those skilled in the art that numerous variations, modifications and substitutions may be made without departing from the spirit of the invention.

The foregoing description details certain embodiments of the invention. It will be appreciated, however, that no matter how detailed the foregoing appears in text, the invention may be practiced in many ways. It should be noted that the use of particular terminology when describing certain features or aspects of the invention should not be taken to imply that the terminology is being re-defined herein to be restricted to including any specific characteristics of the features or aspects of the invention with which that terminology is associated.

While the above detailed description has shown, described, and pointed out novel features of the invention as applied to various embodiments, it will be understood that various omissions, substitutions, and changes in the form and details of the device or process illustrated may be made by those skilled in the technology without departing from the spirit of the invention. The scope of the invention is indicated by the appended claims rather than by the foregoing description. All changes which come within the meaning and range of equivalency of the claims are to be embraced within their scope.

What is claimed is:

1. A method of manufacturing a gate stack on a semiconductor structure comprising:
depositing on a semiconductor structure a high-κ layer comprising a material with a dielectric constant κ higher than the dielectric constant of SiO₂, the semiconductor structure comprising a semiconductor material; and
removing adsorbed and/or absorbed water from the high-κ layer, prior to depositing a gate electrode on the high-κ layer.

2. The method according to claim 1, wherein the removing of adsorbed and/or absorbed water comprises applying a degas treatment.

3. The method according to claim 2, wherein the degas treatment comprises keeping the semiconductor structure in an ambient condition at a temperature in the range approximately between 300° C. and 700° C. during a time period in the range approximately between 30 s and 300 s.

4. The method according to claim 3, wherein the temperature ranges approximately between 350° C. and 600° C.

5. The method according to claim 3, wherein the time period is in the range approximately between 90 s and 180 s.

6. The method according to claim 1, wherein the removing of adsorbed and/or absorbed water comprises keeping the semiconductor structure in an ambient condition at a pressure less than or equal to 10 Torr.

7. The method according to claim 6, wherein the pressure lies in the range approximately between 0.5 mTorr and 10 mTorr when a carrier gas (e.g., Ar, N₂) is used and about less than 1 mTorr when no carrier gas is used.

8. The method according to claim 1, wherein the ambient pressure is maintained at a partial vacuum, between removing the adsorbed and/or absorbed water and deposing a gate electrode.

9. The method according to claim 1, wherein the removing of adsorbed and/or absorbed water comprises keeping the semiconductor structure in an ambient condition with a water vapor partial pressure less than or equal to 10⁻⁴ Torr, preferably less than or equal to 10⁻⁵ Torr.

10. The method according to claim 1, wherein the removing of adsorbed and/or absorbed water and the depositing of a gate electrode are performed in separate process chambers.

11. The method according to claim 10, comprising transferring the semiconductor structure between the separate process chambers under ambient conditions having a water vapor partial pressure less than or equal to about 10⁻³ Torr.

12. The method according to claim 1, wherein the removing of adsorbed and/or absorbed water and of depositing a gate electrode are performed in the same process chamber.

13. The method according to claim 2, wherein the degas treatment is carried out in an ambient condition comprising a carrier gas chosen from the group comprising Ar and N₂.

14. The method according to claim 1, further comprising applying a thermal budget, after depositing a gate electrode.

15. The method according to claim 1, wherein the material with a dielectric constant higher than the dielectric constant of SiO₂ is chosen from the group comprising: Al₂O₃, HfO₂, Hf-silicate, Hf-aluminate, ZrO₂, Zr-silicate, Zr-aluminate, La-aluminate, Hf-lanthanate, Zr-lanthanates, and Hf-zirconates.

16. The method according to claim 1, wherein the gate electrode comprises a metal or the gate electrode is poly Si or fully silicided poly Si.

17. The method according to claim 1, wherein the semiconductor structure further comprises an interfacial oxide layer, wherein the interfacial oxide layer is provided on the semiconductor layer, and wherein the interfacial oxide layer comprises an oxide of the semiconductor material.

18. A method of providing a spacer dielectric against a gate stack, the method comprising:
providing a gate stack comprising a high-κ layer, the high-κ layer comprising a material with a dielectric constant κ higher than the dielectric constant of SiO₂;
patterning the gate stack to obtain a patterned gate stack, thereby exposing the high-κ layer; and
removing adsorbed and/or absorbed water from the high-κ layer prior to depositing a spacer dielectric and covering the high-κ layer at least at one side.

19. The method according to claim 18, wherein the removing of adsorbed and/or absorbed water comprises applying a degas treatment.

20. The method according to claim 19, wherein the degas treatment comprises keeping the patterned gate stack in an ambient condition at a temperature in the range between approximately 300° C. and 700° C. and preferably in the range approximately between 350° C. and 600° C., during a length of time in the range approximately between 30 s and 300 s and preferably in the range approximately between 90 s and 180 s.

21. The method according to claim 18, wherein the removing of adsorbed and/or absorbed water comprises keeping the patterned gate stack in an ambient condition at a pressure less than or equal to about 10 Torr, preferably in the range approximately between 0.5 mTorr and 10 mTorr when a carrier gas is used and less than about 1 mTorr when no carrier gas is used.

22. The method according to claim 18, wherein the removing of adsorbed and/or absorbed water comprises keeping the patterned gate stack in an ambient condition with a water vapor partial pressure less than or equal to about 10⁻⁴ Torr, preferably less than or equal to about 10⁻⁵ Torr.

23. The method according to claim 18, wherein in between the removing of adsorbed and/or absorbed water and the depositing of a spacer dielectric, the ambient pressure is maintained at a partial vacuum, preferably less than or equal to about 10 Torr.

24. The method according to claim 18, wherein the removing of adsorbed and/or absorbed water and the depositing of a spacer dielectric are performed in separate process chambers.

25. The method according to claim 24, comprising transferring the patterned gate stack between the separate process chambers under ambient conditions having a water vapor partial pressure less than or equal to about 10⁻³ Torr.

26. The method according to claim 18, wherein the removing of adsorbed and/or absorbed water and the depositing of a spacer dielectric are performed in the same process chamber.

27. The method according to claim 18, wherein the spacer dielectric is the first of multiple spacer dielectrics deposited.

28. The method according to claim 18, further comprising, after the depositing of a spacer dielectric, patterning the spacer dielectric.

29. The method according to claim 18, further comprising, after the depositing of a spacer dielectric, applying a thermal budget.

30. A method of minimizing the final thickness of an interfacial oxide layer between a semiconductor material and a high-κ layer, the high-κ layer comprising a material with a dielectric constant κ higher than the dielectric constant of SiO₂, the method comprising:
removing adsorbed and/or absorbed water from the high-κ layer prior to depositing a covering layer on the high-κ layer.

31. The method according to claim 30, wherein the removing of adsorbed and/or absorbed water comprises applying a degas treatment.

32. The method according to claim 30, further comprising, after the depositing of a covering layer, applying a thermal budget.

33. The method according to claim 30, wherein the covering layer comprises a gate electrode layer and/or a spacer dielectric.
